(19) United States
(12) Patent Application Publication
(10) Pub. No.: US 2016/0064371 A1
(43) Pub. Date: Mar. 3, 2016

(54) NON-PLANAR ESD DEVICE FOR NON-PLANAR OUTPUT TRANSISTOR AND COMMON FABRICATION THEREOF

(71) Applicant: GLOBALFOUNDRIES Inc., Grand Cayman (KY)

(72) Inventors: Jian-Hsing LEE, Malta, NY (US); Jagar SINGH, Clifton Park, NY (US); Manjunatha PRABHU, Malta, NY (US); Anil KUMAR, Clifton Park, NY (US); Mahadeva Iyer NATARAJAN, Clifton Park, NY (US); Min-hwa CHI, Malta, NY (US)

(73) Assignee: GLOBALFOUNDRIES Inc., Grand Cayman (KY)

(21) Appl. No.: 14/471,712

(22) Filed: Aug. 28, 2014

(51) Int. Cl. H01L 27/02; H01L 21/8249; H01L 27/06

(52) U.S. Cl. CPC H01L 27/0259; H01L 27/0623; H01L 21/8249

(57) ABSTRACT

Protecting non-planar output transistors from electrostatic discharge (ESD) events includes providing a non-planar semiconductor structure, the structure including a semiconductor substrate with a well of n-type or p-type. The provided non-planar structure further includes raised semiconductor structure(s) coupled to the substrate, non-planar transistor(s) of a type opposite the well, each transistor being situated on one of the raised structure(s), the non-planar transistor(s) each including a source, a drain and a gate, the non-planar structure further including parasitic bipolar junction transistor(s) (BJT(s)) on the raised structure(s), each BJT including a collector and an emitter situated on the raised structure and a base being the well, and a well contact for the base of the BJT. Protecting the non-planar output transistors further includes electrically coupling the drain of the non-planar transistor and the collector of the BJT to an output of a circuit, and electrically coupling the source of the non-planar transistor, the emitter of the BJT and the well contact to a ground of the circuit.

### BACKGROUND OF THE INVENTION

1. Technical Field

The present invention generally relates to electrostatic discharge (ESD) devices for semiconductor devices. More particularly, the present invention relates to non-planar ESD devices for, and co-fabricated with, non-planar output transistors.

2. Background Information

Non-planar output transistors frequently experience damaging electrostatic discharge (ESD). In the past, protection for non-planar output transistors against ESD events includes the use of dual diodes and a comparatively large RC power-clamp device. However, RC power-clamp devices significantly increase power consumption, and the dual-diode approach is frequently not adequate protection against high ESD current stress.

Thus, a need exists for a cost-effective way to protect non-planar output transistors from ESD events.

### SUMMARY OF THE INVENTION

The shortcomings of the prior art are overcome and additional advantages are provided through the provision, in one aspect, of a method of protecting non-planar output transistors from electrostatic discharge (ESD) events. The method includes providing a non-planar semiconductor structure, the structure including a semiconductor substrate, including a well of a first type, the first type including one of n-type and p-type, at least one raised semiconductor structure coupled to the substrate, a non-planar transistor of a second type opposite the first type, the transistor being situated on the at least one raised structure, the non-planar transistor including a source, a drain and a gate, and a parasitic bipolar junction transistor (BJT) on the at least one raised structure, the BJT including a collector and an emitter on the at least one raised structure and a base including the well. The method further includes electrically coupling the drain of the non-planar transistor and the collector of the BJT to an output of a circuit, and electrically coupling the source of the non-planar transistor and the emitter of the BJT to a ground of the circuit.

In accordance with another aspect, a non-planar semiconductor structure is provided. The structure includes a semiconductor substrate, including a well of a first type, the first type including one of n-type and p-type. The structure further includes at least one raised semiconductor structure coupled to the substrate, a non-planar transistor of a second type opposite the first type, the transistor being situated on the at least one raised structure, the non-planar transistor including a source, a drain and a gate, and a parasitic bipolar junction transistor (BJT) on the at least one raised structure, the BJT being electrically coupled to the drain of the non-planar transistor, the BJT including a collector and an emitter on the at least one raised structure and a base including the well.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a perspective view of one example of a non-planar semiconductor structure according to one or more aspects of the present invention, the structure including a semiconductor substrate with a well of a first type, a raised semiconductor structure coupled to the substrate, a non-planar transistor of a second type on the raised structure, a parasitic bipolar junction transistor (BJT) on the raised structure using the well as a base, and a well contact of a same type as the well.

FIG. 2 is a perspective view of another example of a non-planar semiconductor structure according to one or more aspects of the present invention, the structure including a semiconductor substrate with a well of a first type, a raised semiconductor structure coupled to the substrate, a non-planar transistor of a second type on the raised structure, a conductive gate surrounding a portion of the non-planar transistor, the conductive gate being electrically coupled to the well, the non-planar transistor also acting as a parasitic bipolar junction transistor (BST), and a BJT on the raised structure using the well as a base.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

Reference is made below to the drawings, which are not drawn to scale for ease of understanding, wherein the same reference numbers are used throughout different figures to designate the same or similar components.

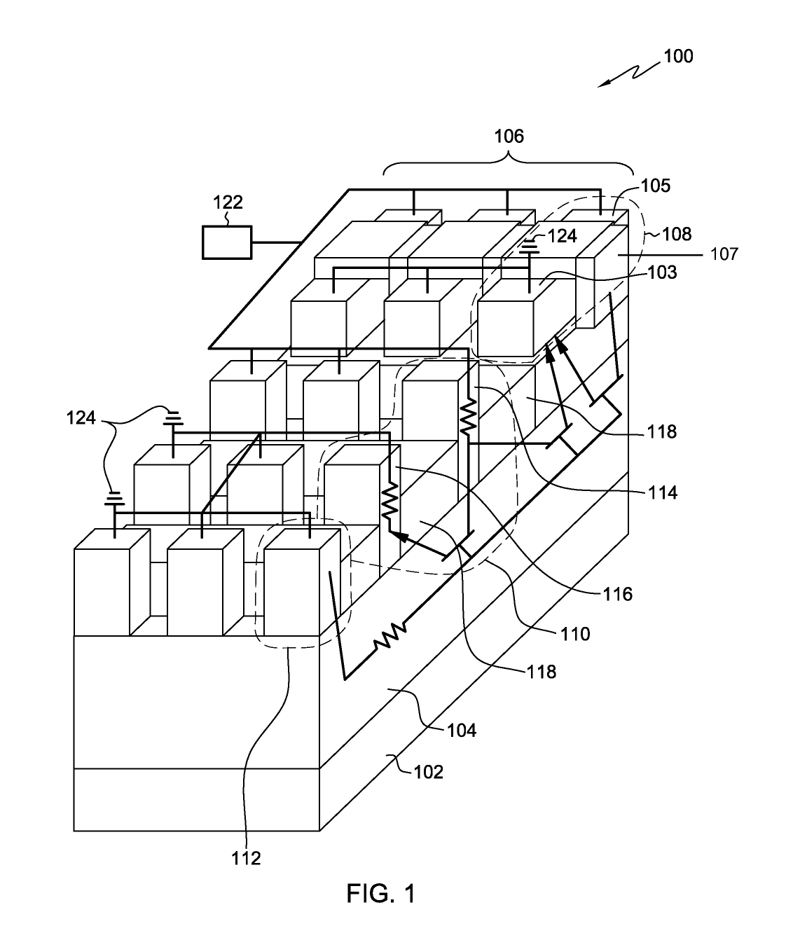

FIG. 1 is a perspective view of one example of a non-planar semiconductor structure 100, according to one or more aspects of the present invention. The structure includes a semiconductor substrate 102 with a well 104 of a first type therein, one or more raised semiconductor structures 106 coupled to the substrate, a non-planar transistor (e.g., non-planar transistor 108) of a second type on each raised structure, a parasitic bipolar junction transistor (BJT) (e.g., BJT 110) on each raised structure, each BJT using the well as a base, and one or more well contacts (e.g., well contact 112) of a same type as the well.

In one example, substrate 102 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. Substrate 102 may in addition or instead include various isolations, dopings and/or device features. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof.

In one example, raised structure(s) 106 may take the form of “fins.” The raised structure(s) may be etched from a bulk substrate, SOI or the like, and may include, for example, any of the materials listed above with respect to the substrate. Further, some or all of the raised structure(s) may include added impurities (e.g., by doping), making them n-type or p-type. The non-planar transistor(s) each include a source (e.g., source 103), a drain (e.g., drain 105), and a gate structure (e.g., gate structure 107) surrounding a portion of each non-planar transistor. In one example, the gate structure(s) include dummy gate structure(s), including, for example, polycrystalline silicon.

Each parasitic bipolar transistor is of a same type as its corresponding non-planar transistor (e.g., NPN BJT for n-type FinFET), and includes a collector (e.g., collector 114) and an emitter (e.g., emitter 116) situated on the raised structure(s) 106. Isolation material 118 separates the BJT from the non-planar transistor, and also separates the collector and the emitter. The isolation material may include, for example, shallow trench isolation (STI) material, or, as another example, may include polycrystalline silicon. The well 104 acts as a base for the BJT. As can be seen in FIG. 1, the emitter(s) and collector(s) have deeper implant(s), for example, about twice as deep as the source(s) or drain(s) of the transistor(s), for example, implant(s) of about 10 nm to about 500 nm. Also on each raised structure is a well contact (e.g., well contact 112) of a same type as the well, and separated from the BJT by the isolation material. Preferably, the implant for the well contact has a depth similar to that of the BJT.

Also shown in FIG. 1 are electrical couplings (in this example, connections) between the various elements of the structure 100. The drain(s) of the transistor(s), the collector(s) of the BJT(s) and the well contact(s) are commonly electrically coupled to an output 122 (in this example, a pad) of a circuit (not shown for clarity), while the source(s) of the transistor(s), the emitter(s) of the BJT(s) and the well contact(s) are commonly electrically coupled to a ground 124 of the circuit.

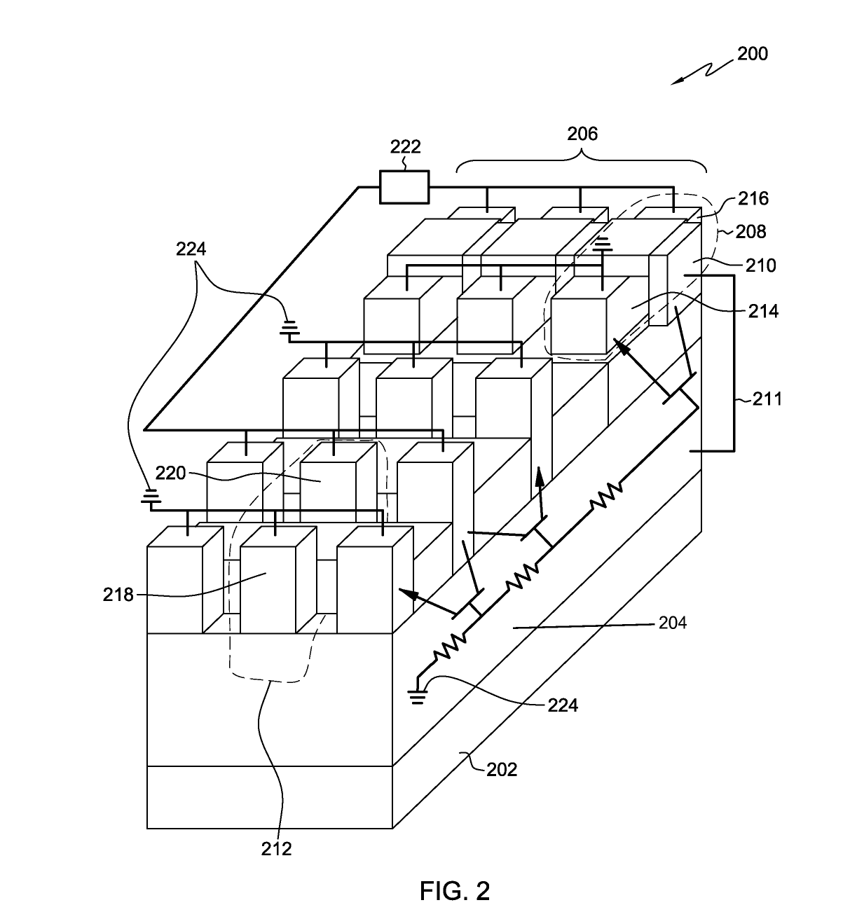

FIG. 2 is a perspective view of another example of a non-planar semiconductor structure 200, according to one or more aspects of the present invention. The structure includes a semiconductor substrate 202 with a well 204 of a first type therein, one or more raised semiconductor structures 206 coupled to the substrate, a non-planar transistor (e.g., transistor 208) of a second type on each raised structure, including a conductive gate 210 surrounding a portion of the non-planar transistor, the conductive gate being electrically coupled 211 to the well, and a parasitic bipolar junction transistor (BJT) of a same type as the non-planar transistor on each raised structure (e.g., BJT 212), the BJT(s) being separated from the non-planar transistor(s) by isolation material, which would also be between raised structures, but is not shown here for clarity. Each BJT includes an emitter (e.g., emitter 218), a collector (e.g., collector 220) and a base (well 204 acts as the base).

Aside from the conductive gate (e.g., gate 210), each non-planar transistor includes a source (e.g., source 214) and a drain (e.g., drain 216), and is of a second type (n-type or p-type) opposite that of the well. Note that the emitter(s) and collector(s) of the BJT(s) have a deeper implant than the drain(s) and source(s) of the non-planar transistor(s), for example, about twice as deep. The non-planar transistor(s) also act as parasitic BJT(s), with the drain(s) acting as collector(s), the source(s) acting as emitter(s) and the well acting as the base of the BJT(s), the conductive gate(s) acting as the well contact(s). As shown, the collector(s) of the BJT(s) and the drain(s) of the non-planar transistor(s) are electrically coupled to an output 222 of a circuit (not shown for clarity), while the source(s) of the non-planar transistor(s) and the emitter(s) of the BJT(s) are electrically coupled to a ground 224 of the circuit.

In a first aspect, disclosed above is a method of protecting non-planar output transistors from electrostatic discharge (ESD) events. The method includes providing a non-planar semiconductor structure, the structure including a semiconductor substrate with a well of n-type or p-type. The structure provided further includes raised semiconductor structure(s) coupled to the substrate, a non-planar transistor of a type opposite the well being situated on the raised structure(s), each non-planar transistor including a source, a drain and a gate. The structure provided further includes parasitic bipolar junction transistor(s) (BJT) on the raised structure(s), each BJT including a collector and an emitter on the relevant raised structure and a base including the well. The method further includes electrically coupling the drain(s) of the non-planar transistor(s) and the collector(s) of the BJT(s) to an output of a circuit, and electrically coupling the source(s) of the non-planar transistor(s), the emitter(s) of the BJT(s) and the well contact(s) to a ground of the circuit.

In one example, the provided non-planar semiconductor structure further includes a well contact for the base of each BJT, the method further including electrically coupling the well contact(s) to the ground of the circuit. In one example, the well contact(s) is situated on the raised semiconductor structure(s) and is a same type as the well. Where the well contact(s) is on the raised structure(s) and is a same type as the well, the method may further include, for example, electrically coupling the emitter(s) to the well contact(s).

In one example, the well contact(s) includes a diode(s) of the same type as the well.

In another example, the gate(s) may include, for example, a conductive material, and acts as the well contact(s).

In a second aspect, disclosed above is a non-planar semiconductor structure. The structure includes a semiconductor substrate, including a well of n-type or p-type therein. The structure further includes raised semiconductor structure(s) coupled to the substrate, non-planar transistor(s) of a type opposite the well, the transistor(s) being situated on the raised structure(s), each non-planar transistor including a source, a drain and a gate, and parasitic bipolar junction transistor(s) (BJT) on the raised structure(s), each BJT being electrically coupled to the drain of the non-planar transistor, the BJT including a collector and an emitter on the raised structure(s) and a base including the well.

In one example, the non-planar structure of the second aspect may further include, for example, a well contact for the base of each BJT.

The well contact(s) may be, for example, a diode(s) of the same type as the well situated on the raised semiconductor structure(s). Further, the collector(s) of the BJT(s) and the drain(s) of the non-planar transistor(s) may both be electrically coupled to an output of a circuit, and the source(s), the emitter(s) and the diode(s) may be electrically coupled to a ground of the circuit.

In another example, where the non-planar structure of the second aspect includes a well contact for the base of the BJT(s), the gate(s) may include a conductive material that is electrically coupled to the well, the gate(s) acting as the well contact(s). In addition, the drain(s) of the non-planar transistors(s) and the collector(s) of the BJT(s) may be electrically coupled to an output of a circuit, and the source(s), emitter(s) and the well may be electrically coupled to a ground of the circuit.

In one example, the well of the non-planar structure of the second aspect may be p-type, the non-planar transistor may be n-type, and the parasitic BJT may be a NPN BJT.

In another example, the well of the non-planar structure of the second aspect may be n-type, the non-planar transistor may be p-type, and the parasitic BJT may be a PNP BJT.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a non-planar semiconductor structure, the structure comprising:
a semiconductor substrate, comprising a well of a first type, the first type comprising one of n-type and p-type;
at least one raised semiconductor structure coupled to the substrate;
a non-planar transistor of a second type opposite the first type, the transistor being situated on the at least one raised structure, the non-planar transistor comprising a source, a drain and a gate; and
a parasitic bipolar junction transistor (BJT) separate from the non-planar transistor on the at least one raised structure, the BJT comprising a collector and an emitter on the at least one raised structure and a base comprising the well;
electrically coupling the drain of the non-planar transistor and the collector of the BJT to an output of a circuit; and
electrically coupling the source of the non-planar transistor and the emitter of the BJT to a ground of the circuit.

2. The method of claim 1, wherein the provided non-planar semiconductor structure further comprises a well contact for the base of the BJT, the method further comprising electrically coupling the well contact to the ground of the circuit.

3. The method of claim 2, wherein the well contact is situated on the at least one raised semiconductor structure and is a same type as the well.

4. The method of claim 3, further comprising electrically coupling the emitter to the well contact.

5. (canceled)

6. The method of claim 2, wherein the gate comprises a conductive material, the method further comprising electrically coupling the gate to the well, the gate comprising the well contact.

7. A non-planar semiconductor structure, comprising:
a semiconductor substrate, comprising a well of a first type, the first type comprising one of n-type and p-type;
at least one raised semiconductor structure coupled to the substrate;
a non-planar transistor of a second type opposite the first type, the transistor being situated on the at least one raised structure, the non-planar transistor comprising a source, a drain and a gate; and
a parasitic bipolar junction transistor (BJT) separate from the non-planar transistor on the at least one raised structure, the BJT being electrically coupled to the drain of the non-planar transistor, the BJT comprising a collector and an emitter on the at least one raised structure and a base comprising the well.

8. The non-planar semiconductor structure of claim 7, further comprising a well contact for the base of the BJT.

9. (canceled)

10. The non-planar semiconductor structure of claim 8, wherein the collector of the BJT and the drain of the non-planar transistor are both electrically coupled to an output of a circuit, and wherein the source, the emitter and the well contact are electrically coupled to a ground of the circuit.

11. The non-planar semiconductor structure of claim 8, wherein the gate comprises a conductive material and is electrically coupled to the well, the gate comprising the well contact.

12. The non-planar semiconductor structure of claim 11, wherein the drain of the non-planar transistor and the collector of the BJT are electrically coupled to an output of a circuit, and wherein the source of non-planar transistor, the emitter of the BJT and the well are electrically coupled to a ground of the circuit.

13. The non-planar semiconductor structure of claim 7, wherein the first type comprises p-type, wherein the second type comprises n-type, and wherein the parasitic BJT comprises a NPN BJT.

14. The non-planar semiconductor structure of claim 7, wherein the first type comprises n-type, wherein the second type comprises p-type, and wherein the parasitic BJT comprises a PNP BJT.
